(19) United States
(12) Patent Application Publication
(10) Pub. No.: US 2013/0075381 A1
(43) Pub. Date: Mar. 28, 2013

(54) Occupant sensing and heating textile

(71) Applicant: Thomas Wittkowski, Hermeskeil (DE)

(72) Inventor: Thomas Wittkowski, Hermeskeil (DE)

(73) Assignee: IEE INTERNATIONAL ELECTRONICS & ENGINEERING S.A., Echternach (LU)

(21) Appl. No.: 13/637,517

(22) PCT Filed: Mar. 28, 2011
(86) PCT No.: PCT/EP2011/054663

§ 371 Date: Dec. 6, 2012

(30) Foreign Application Priority Data
Mar. 26, 2010 (LU) 91 671

(51) Int. Cl. H01B 5/00; H05B 3/02; H01B 19/04; G01R 27/02

(52) U.S. Cl. CPC H01B 5/00; G01R 27/02; H05B 3/02; H01B 19/04
USPC 219/201; 174/126.2; 324/658; 29/846

(57) ABSTRACT

A textile electrode material comprises an electrically conductive textile sheet material having a first sheet resistance. According to the invention the electrical properties of at least one specific region of said textile sheet material are modified with respect to the other regions so that in said specific region the textile electrode has a second sheet resistance, which is substantially lower than said first sheet resistance.

### INTRODUCTION

The present invention generally relates to occupant detection systems (ODS) or occupant classification systems (OCS), and heating in the seating surface of vehicles by employing conductive textiles.

Textile based occupant detection systems or occupant classification systems are designed to be fully functional over a vehicles lifetime, which is at least 15 years. Seat heaters, however, are frequently failing after only a few years of operation. Today's concept of constructing and producing seat heaters including their material concepts severely limit their robustness. Hence today's way of producing seat heaters cannot be transferred to producing textile sensor electrodes for safety relevant applications such as occupant detection systems or occupant classification systems. Neither is it possible to combine occupant detection system or occupant classification system functionality and a seat heater on a same textile area when using the construction, production, and material concepts of either today's seat heaters or of today's textile occupant detection systems or occupant classification systems.

Textile sensor electrodes for occupant classification systems that base on capacitive measurement are usually built from a PET woven, which is plated with nickel. This material system fulfills hardest automotive seating requirements. Even though this material possesses typical textile attributes such as flexibility, suppleness, and air permeability it is far from being an ideal solution in view of elasticity, air permeability, and allergic potential. Furthermore the very low sheet resistance of such a plated PET textile discards this material from being used as seat heater. It is plated in a continuous reel-to-reel process, which leads to constant amount of metal per textile area unit across the roll.

Regarding textile seat heaters, different concepts can be found, such as:
1. a heating yarn in a textile matrix. The heating yarn may be composed of carbon fibers, metal (yarn or wires) or metal plated polymer.
2. printed conductive heating areas, mostly printed on non-woven materials.

Both the above seat heater concepts are unsuited for capacitive occupant sensing. Insufficiencies are manifold, such as: too high resistance, heating yarn/wire prone to breakage, inhomogeneous properties of resistance causing either hot spots or leading to short circuits in sensing systems comprising more than one conducting textile layer, inhomogeneous temperature distribution, no redundancy in case of wire break, resistance varies while bending the textile, not abrasion resistant, mechanically not robust enough (non-woven lack an adequate elastic response upon tensile stress), too impermeable to air, need protection coatings which are also impermeable to air. Existing seat heater embodiments thus may limit the seat comfort. Without exclusion all seat heaters do not fulfill the mechanical and environmental requirements for OCS where a sensor lifetime over 15 years minimum must be warranted.

### OBJECT OF THE INVENTION

The object of the present invention is to provide an improved material for occupant sensing and seat heating.

### General Description of the Invention

In order to overcome at least one of the above mentioned problems, the present invention proposes a textile electrode material comprising an electrically conductive textile sheet material, said textile sheet material having a first sheet resistance. According to the invention, the electrical properties of at least one specific region of said textile sheet material are modified with respect to the other regions so that in said specific region the textile electrode has a second sheet resistance, which is substantially lower than said first sheet resistance.

Textile electrodes are provided with conductance so that they fulfill toughest requirements regarding tolerances in electrical resistance, mechanical and environmental robustness as well as pricing, all of which are mandatory requirements in the automotive ODS/OCS seating application. New concepts for materials, construction, and production process of textile electrodes are employed. These combine the application of materials of different conductance in the textile, where one of the materials is integrated in a characteristic structure in the textile plane. The invention enables/describes the combination of sensing for ODS/OCS and heating on a single textile sheet. The invention discloses the build-up of preferable textile materials, the construction of textile electrodes for sensing and/or heating, and ways of electrical contacting.

In preferred embodiments of the invention, said textile sheet material comprises a knitted fabric or a woven fabric or an elastic non-woven material made at least partially from electrically conductive yarns, such as yarns containing metal fibers or yarns containing fibers individually coated with electrically conductive material (such as metals or carbon black or others) or yarns are made conductive in a finishing process whereby all the fibers in the yarn are coated with an electrically conductive material. Alternatively said textile sheet material comprises a knitted fabric or a woven fabric or an elastic non-woven material made from electrically non-conductive yarns and wherein the electrical conductivity is provided in a textile finishing process. In this embodiment, the entire fabric material is made conductive in a finishing process whereby all or at least most of the fibers of the yarns are coated with an electrically conductive material.

In one possible embodiment of the invention, the second sheet resistance in said at least one specific region is obtained by a layer of highly conductive material (such as metal or carbon black or others) printed or deposited in said at least one specific region on said textile sheet material. Alternatively the second sheet resistance in said at least one specific region is obtained by the stitching of highly conductive yarns in said at least one specific region on said textile sheet material.

In yet another embodiment, especially in the case of textile materials made by knitting or weaving of conductive yarns, the second sheet resistance in said at least one specific region may be obtained by locally delimited areas or structures of highly conductive material printed or deposited in said at least one specific region on said textile sheet material. These highly conductive structures do not act as electrodes, instead they ensure optimum electrical contacting of conductive yarns in the points of yarn crossings. Hence these structures will be referred to as connecting dots.

The connecting dots solve a typical problem, which frequently occurs in textiles made of conductive yarns. The contact resistance at the yarn crossings largely depends upon the mechanical strain state of the textile. In addition the surface of conductive filaments may alter as a function of time depending on the prevailing environmental conditions. Typically the contact resistance at the yarn crossings increases after such aging.

At those positions on the textile material where a connecting dot is applied, this connecting dot ensures an optimum electrical contact (lowest contact resistance) between the different yarns and yarn filaments in the area of the dot. The connecting dot is most advantageous if yarns of weft and warp direction are crossing within its area.

The connecting dots ensure that all yarns and filaments within its area are at approximately the same electrical potential. In consequence the electrical properties of the above specified conductive textile are drastically enhanced: 1. Its sheet resistance becomes much more homogeneous. 2. Its sheet resistance tends to be lower than without connecting dots. 3. Sheet resistance of the conducting textile with connecting dots is much more robust against local damage of the textile typically accompanied by a local increase of resistance.

The present invention also relates to sensing or heating systems employing the textile electrode material as described hereinabove. One possible embodiment of such a system is a capacitive sensing system comprising a capacitive sensing electrode made of a textile electrode material and a capacitive sensing circuit for applying a signal to said capacitive sensing electrode or receiving a signal from said capacitive sensing electrode. In such a system, said capacitive sensing circuit is operatively connected to said at least one specific region, which then forms the highly sensitive capacitive electrode portion.

In another application, the above described textile electrode material may be used in a seat heating system e.g. for an automotive vehicle. Such a heating system may e.g. comprise a heating element made of a textile electrode material and a heater supply circuit for applying a heating current to said heating element. The textile electrode material preferably comprises at least two specific regions in which the textile electrode has said second sheet resistance, said two specific regions being arranged at a certain distance one to the other, and wherein said heater supply circuit is operatively connected to said at least two specific regions so as to cause, in operation, a heating current to flow between said at least two specific regions through a region having said first sheet resistance of said textile electrode material.

The present invention also relates to a method for producing a textile electrode material as substantially described hereinabove. Such a method may e.g. comprise the steps of:
providing an electrically conductive textile sheet material, said textile sheet material having a first sheet resistance,
providing at least one highly conductive electrode area in said electrically conductive textile sheet material by modifying the electrical properties of at least one specific region of said textile sheet material with respect to the other regions so as to increase the electrical conductivity so that in said least one specific region the textile electrode has a second sheet resistance which is substantially lower than said first sheet resistance.

It should be noted that two different approaches are possible for the production of this material:
A.) The conductive textile is prepared first and highly conductive electrodes are applied after. In this case the conductive textile is prepared either by weaving or knitting or by a textile printing or finishing process and the highly conductive electrode is prepared in a printing or in a stitching process.
B.) The highly conductive electrodes are prepared first and the whole textile is provided with conductivity after. In this case the highly conductive electrode is prepared by stitching, weaving, knitting or printing and the conductive textile is prepared in a printing or in a finishing process.

In the case of scenario A), the step of providing at least one highly conductive electrode area comprises the printing or depositing of a layer of highly conductive material in said at least one specific region on said electrically conductive textile sheet material. Alternatively, said step of providing at least one highly conductive electrode area comprises the printing or depositing of locally delimited areas of highly conductive material in said at least one specific region on said electrically conductive textile sheet material, or said step of providing at least one highly conductive electrode area comprises the stitching of highly conductive yarns in said at least one specific region on said electrically conductive textile sheet material.

In the case of scenario B), said step of providing at least one highly conductive electrode area comprises the stitching, weaving or knitting of highly conductive yarns in said at least one specific region on an electrically non-conductive textile sheet material, and the step of providing an electrically conductive textile sheet material comprises the subsequent provision of electrical conductivity to said electrically non-conductive textile sheet material in a textile printing process or a textile finishing process. Alternatively said step of providing at least one highly conductive electrode area comprises the printing of highly conductive materials in said at least one specific region on an electrically non-conductive textile sheet material, and the step of providing an electrically conductive textile sheet material comprises the subsequent provision of electrical conductivity to said electrically non-conductive textile sheet material in a textile printing process or a textile finishing process.

In conclusion it will be noted that the present invention provides the integration of a capacitive sensing electrode and a heater in a textile material, which is to be electrically connected and integrated in a vehicle seat. The configuration of textile materials is disclosed which enable this hybrid functionality and which fulfill hardest automotive seating requirements. Such materials and hybrid constructions did not exist up to now.

### DETAILED DESCRIPTION WITH RESPECT TO THE FIGURES

The present invention will be more apparent from the following description of several not limiting embodiments with reference to the attached drawings, wherein

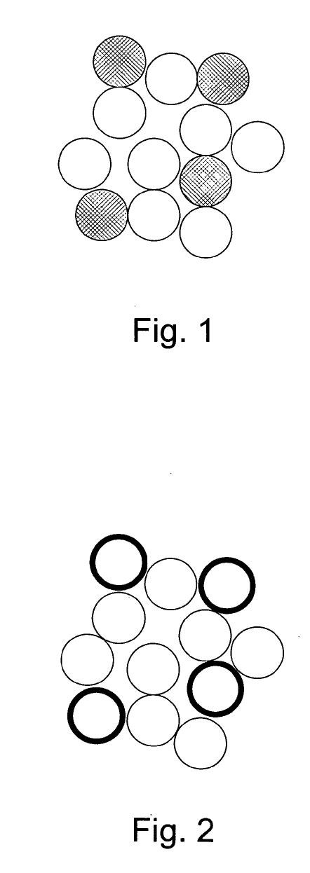

FIG. 1: shows section of a first embodiment of a yarn to be used in the production of an electrode material;

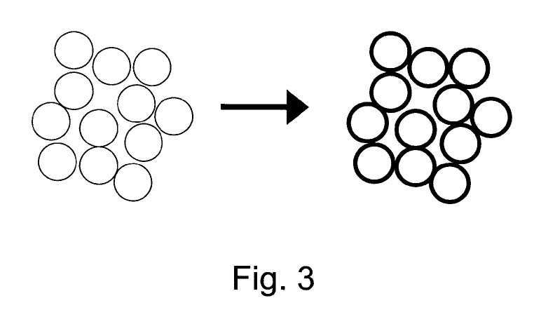

FIG. 2: shows section of a second embodiment of a yarn to be used in the production of an electrode material;

FIG. 3: shows section of a third embodiment of a yarn to be used in the production of an electrode material;

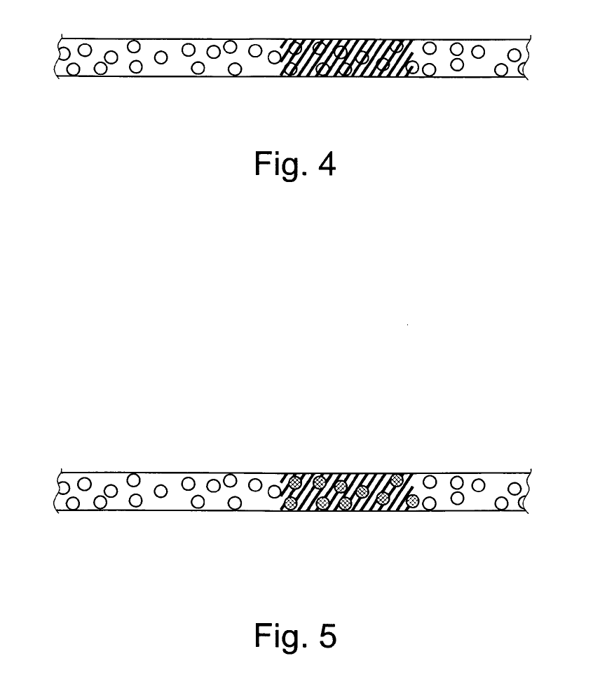

FIG. 4: shows section of a part of a first embodiment of an electrode material;

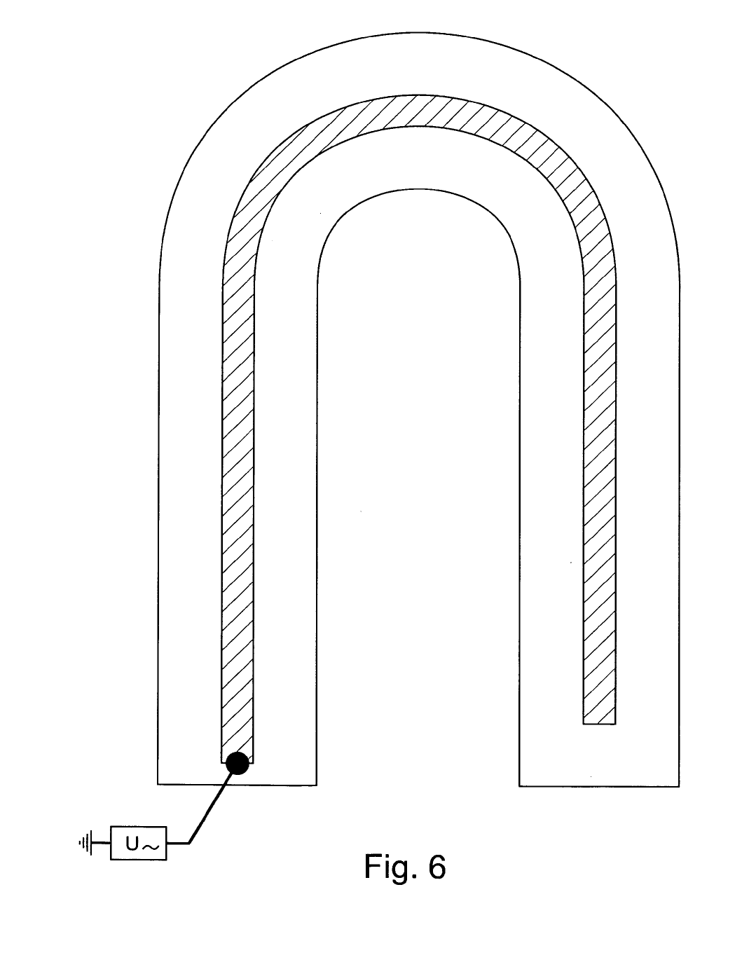

FIG. 5: shows section of a part of a second embodiment of an electrode material;

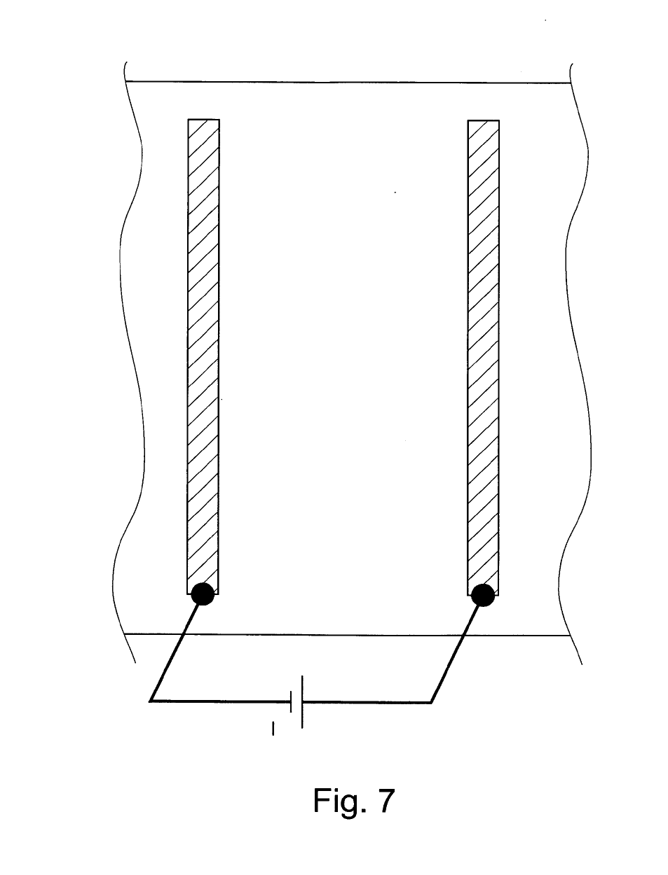

FIG. 6: shows an embodiment of a capacitive sensing system;

FIG. 7: shows a first embodiment of a heating system;

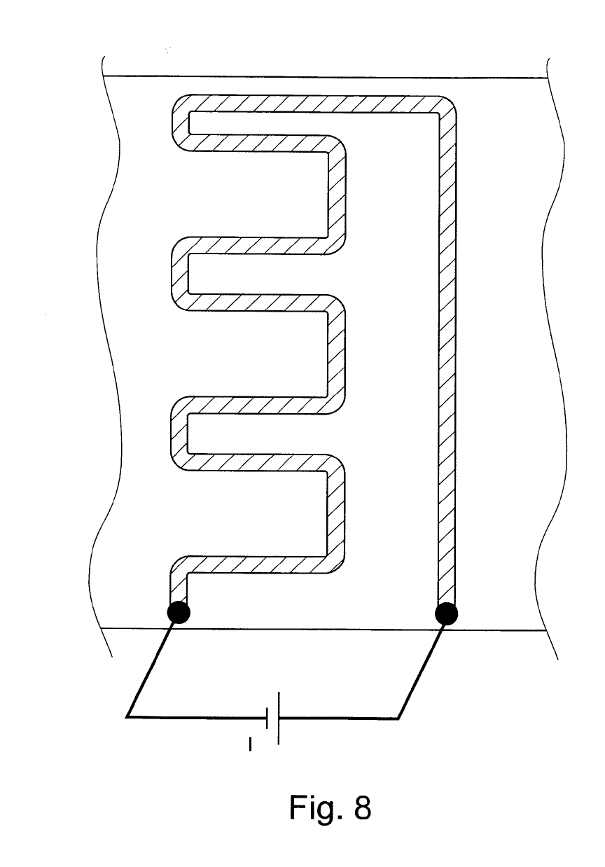

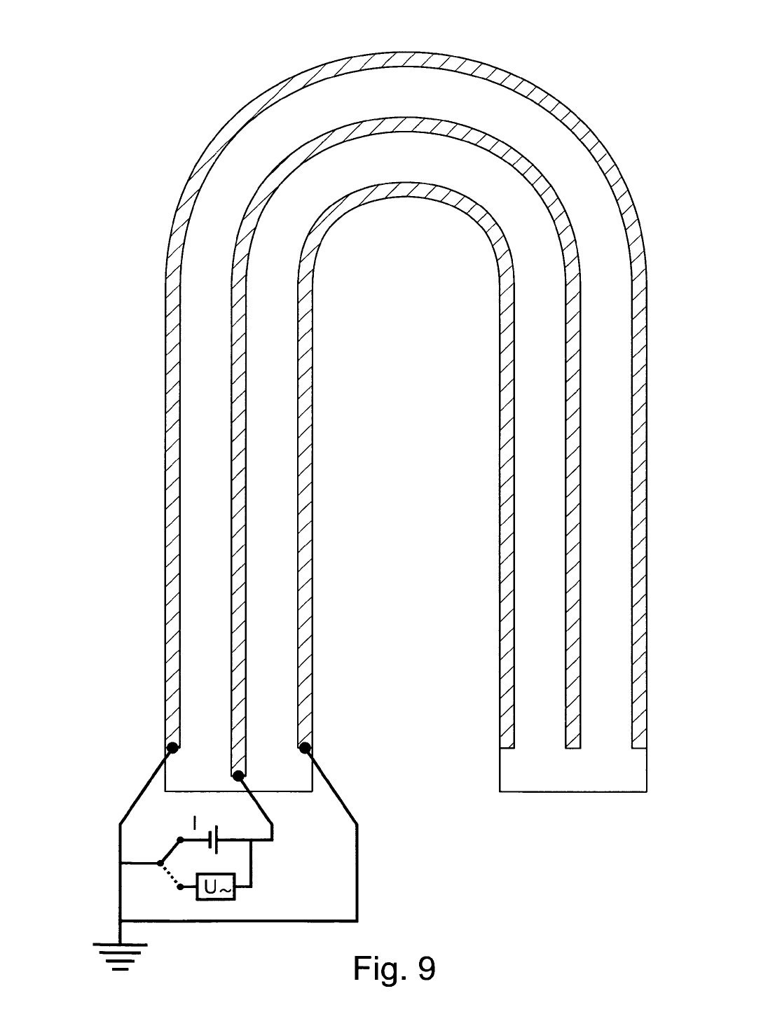

FIG. 8: shows a second embodiment of a heating system;

FIG. 9: shows an embodiment of a combined heating and sensing system;

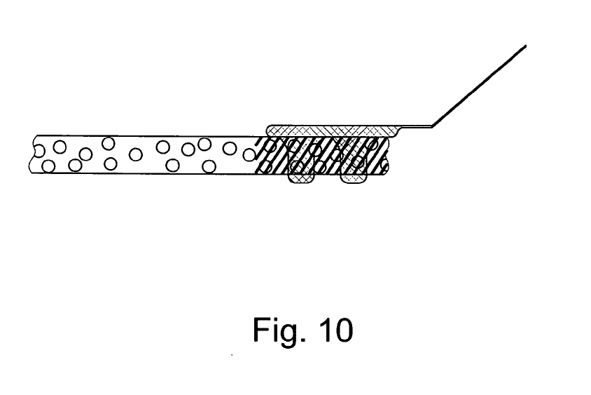

FIG. 10: a first embodiment of a crimp contact for contacting a textile electrode material;

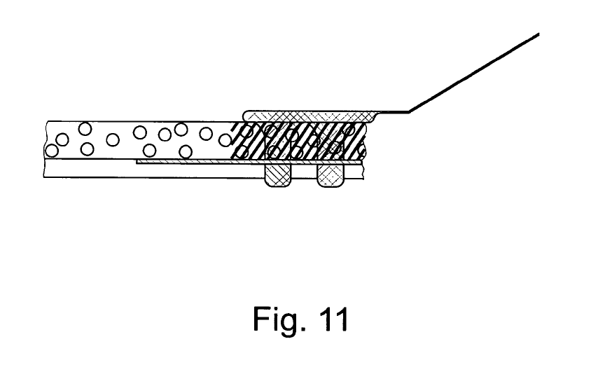

FIG. 11: a second embodiment of a crimp contact for contacting a textile electrode material;

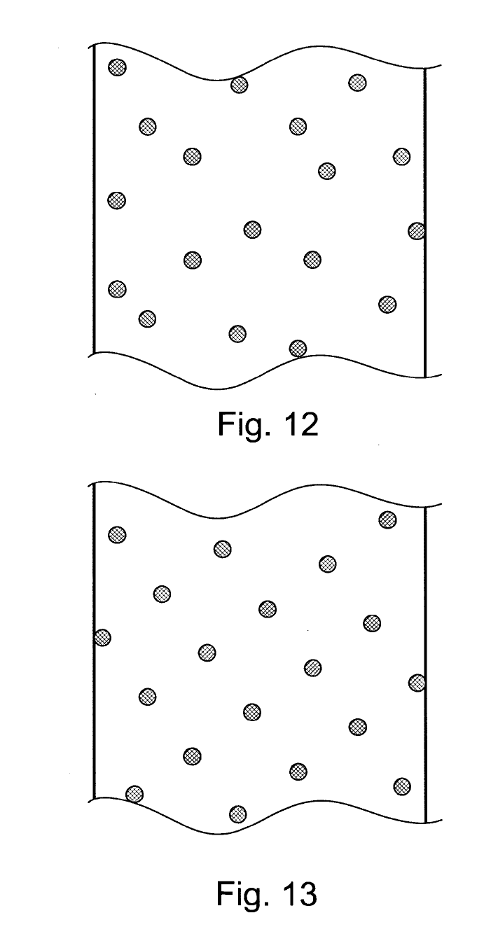

FIG. 12: a top view of a section of an embodiment of a textile electrode material, in which the highly conductive areas are obtained by the application of contacting dots;

FIG. 13: a top view of a section of a different embodiment of a textile electrode material, in which the highly conductive areas are obtained by the application of contacting dots.

Sensors or heaters in accordance with the disclosure of the present invention are made from a single textile sheet material. This textile exhibits electrical conductance. The sheet resistance, Rsq, of the textile is typically in the range between 10 and 1000 Ohm per square. Selected areas of the textile, so-called electrodes, exhibit a sheet resistance Rsq typically between 0.01 and 10 Ohm per square.

The specific textile construction is not part of the invention. Preferably knitted fabrics, woven or elastic non-woven will be used.

The textile is made from yarns, which can be different in nature. In general a non-limited number of different yarns (different in the sense of yarn count, filament number, filament materials) can be used to produce a textile. It will be noted that the invention is not limited to textiles made from yarns of different type, but the option of using different yarns in the textile material is included. Preferred yarn materials are polyester or polyamide but all other yarn materials are also possible.

Creation of the conductive textile is provided either by employing conductive yarns or by using any process for textile post-treatment. This means that conductance is either provided in the process of weaving or knitting, or it is provided in a textile printing or in a finishing process.

Possible embodiments of conductive yarns used in a weaving or knitting process are illustrated in FIGS. 1 and 2. Yarns that are provided with conductivity in a textile printing or finishing process are illustrated in FIG. 3.

Creation of electrode areas in the conductive textile is provided either by employing highly conductive yarns or by applying a conductive ink. This means that the high electrode conductance is either provided in the process of stitching, structured weaving or knitting, or it is provided in a textile printing process. Possible embodiments of conductive yarns to be used in a stitching, structured weaving or knitting process are illustrated in FIGS. 1 and 2. Yarns that are provided with conductivity in a textile printing process are illustrated in FIG. 3.

Materials for full metal filaments, as used in the embodiment shown in FIG. 1, are preferably stainless steel, brass, silver-plated brass, bronze, steel clad copper or copper clad steel, and all other suitable elemental metals or multilayer or alloys thereof. Coating materials of the coated filaments, as used in the embodiment shown in FIG. 2, are preferably silver, nickel, tin, and all suitable elemental metals or alloys thereof. The coating material of the coated filaments can also consist of a composite of metal particles and a binder, carbon black (CB) and a binder or of carbon nanotubes (CNT) and a binder.

Coating materials applied in a textile printing or finishing process. As illustrated in FIG. 3, are preferably composites of metal clusters or particles (silver, e.g.) and a binder, composites of CB and a binder, composites of CNTs and a binder and combinations of different composites. Coating materials applied in a textile printing or finishing process may also consist of composites of intrinsically conducting polymers and a binder.

The drawings show in particular:

FIG. 1: Yarn containing full metal filaments. Cross-section of a yarn with 12 filaments (as example). Polymer (metal) filaments are indicated by the white (black) cross-sections. The portion of the full metal filaments in the yarn (i.e. the ratio of coated to non-coated filaments) is chosen between 10 and 100%. The ration of the number (and/or mass) is e.g. adjusted in the spinning process of the yarn.

FIG. 2: Yarn containing coated filaments. Cross-section of a yarn with 12 filaments (as example). Polymer filaments are indicated by the white cross-sections. The filament conductive coating is indicated by a thick black borderline of the circular cross-sections. The portion of the coated filaments in the yarn (i.e. the ratio of coated to non-coated filaments) is chosen between 10 and 100%. The respective ration is e.g. adjusted in the spinning process of the yarn.

FIG. 3: Yarn before and after textile printing or finishing process. Cross-section of a yarn with 12 filaments (example). Polymer filaments are indicated by the white cross-sections. The filament conductive coating is indicated by a thick black borderline of the circular cross-sections. All filaments are coated in a textile printing of finishing process. The left (right) figure displays the yarn cross-section before (after) the coating process. Depending on the yarn and the process type in reality the limited infiltration of the yarn may lead to lower coating thickness of filaments in the yarn center than of those lying at the outer surface of the yarn.

One may distinguish two cases.
A.) The conductive textile is prepared first and highly conductive electrodes are applied after. In this case the conductive textile is prepared either by weaving or knitting or by a textile printing or finishing process and the highly conductive electrode is prepared in a printing or in a stitching process.
B.) The highly conductive electrodes are prepared first and the whole textile is provided with conductivity after. In this case the highly conductive electrode is prepared by stitching, weaving, knitting or printing and the conductive textile is prepared in a printing or in a finishing process.

FIGS. 4 and 5 schematically illustrate cases A and B. Note that the highly conductive electrode is always applied in a process that enables the provision of high conductance in well-defined lateral structure of the textile area. On the other hand the conductive textile is not necessarily prepared in a process that provides laterally structured conductance, i.e. the complete width of a roll of textile may be provided with conductance. A typical process to provide the textile with conductance in an unstructured manner across the roll would e.g. be the Foulard process frequently used in textile finishing.

FIG. 4 shows a schematic cross-section of a textile where the conductive textile sheet material is prepared first and highly conductive electrode structures are prepared after (production scenario A.)). The textile structure is not resolved in the drawing.

FIG. 5 shows a schematic cross-section of a textile where the highly conductive electrode structures are prepared first and the conductance of the textile sheet material is provided afterwards (production scenario B.)). The textile structure is not resolved in the drawing.

Such prepared conductive textile and highly conductive electrodes may be employed to produce electromechanically robust, long-term stable sensor electrodes and heaters integrated in vehicle seats that fulfill automotive requirements over vehicle lifetime in automotive safety applications (ODS/OCS). The following FIGS. 6 to 10 illustrate the working principles of possible embodiments of such systems or applications. These embodiments are independent of the specific production scenario A.) or B.) as described above.

It should further be noted that the optimum choice of textile construction, materials, and processes depends upon externally defined parameters such as seat size, sensor integration concept, capacitive sensor electrode area, capacitive sensor operating frequency, seat heater power take-up, area distribution of seat heater temperature or power, and the electronic concept (duty cycles, etc.) to integrate capacitive sensor electrode and seat heater in a single textile sheet. FIGS. 6 to 9 hence illustrate different basic working principles in a schematic way.

FIG. 6 shows a schematic top view of a capacitive electrode (U-shape) integrated in a vehicle seat. A time-varying electric voltage signal, U˜, is applied at the highly conductive electrode (hatched area). Due to the highly conductive electrode in the center of the U-shaped sensor the electrical potential varies only little across the complete electrode area. Because of the highly conductive electrode the characteristic time constant RC of the electrode is small so that capacitive measurements at frequencies higher than 100 kHz are enabled. For the capacitive OCS measurement the change in impedance due to seat occupation must be dominated by the imaginary part of the measurement signal. A small RC of the electrode as is achieved by the highly conductive electrode is thus favorable.

FIG. 7 shows a schematic top view of a seat heater with predominantly parallel electrical design. Heating power is mainly dissipated in the region of the conductive textile between the highly conductive electrodes (hatched area).

FIG. 8 shows a schematic top view of seat heater with predominantly serial electrical design. Heating power is predominantly dissipated along the path of the meander shaped, highly conductive electrode (hatched area).

FIG. 9 shows a schematic top view of a combination of capacitive sensor electrode and seat heater. The U-shape was chosen as in FIG. 6 for the ease of illustration. Additional inner and outer highly conductive electrodes (hatched areas) are applied in order to provide a predominantly parallel electrical seat heater design. The sensor operation may be switched between capacitive sensing and heating.

For sensor and for heater operation the highly conductive electrode is contacted to leads via connectors. The highly conductive electrode provides the conductive textile with an additional mechanical stiffness, which in consequence allows for the use of crimp connectors between leads and highly conductive textile. This advantage holds for both production scenarios, A.) and B.).

It can be advantageous to further reinforce the crimp area with a strip of electrically conducting polymer film. This polymer film can be applied either on the crimp side or on the opposite side of the textile. It is possible to provide the conductive polymer film by a laterally structured conductive layer applied on one side of an insulating polymer film. In this case the conductive side of the polymer film may be oriented towards the highly conductive electrode or towards the opposite direction.

Leads may also be glued preferably using ICA (isotropic conductive adhesive).

Crimped or glued contacts are protected against too high mechanical tensile or bending stress as well as against climatic conditions such as high temperature, high humidity or thermal shocks by an encapsulation with a suitable thermoplastic or thermoset polymer. This encapsulation can be applied by pouring the liquid polymer onto the connector and the textile or it can be cast into an appropriate mold around the connector.

FIG. 10 schematically illustrates a cross-section of a crimp contact. The crimp cross-section is displayed cross-hatched. The supplementary material of the highly conductive electrode mechanically stiffens the conductive textile and warrants a low contact resistance between crimp and highly conductive electrode. The figure shows the production scenario A.) where the conductive textile was prepared first and the highly conductive electrode was prepared after.

FIG. 11 shows a schematic cross-section of another variant of a crimp contact. The crimp cross-section is displayed cross-hatched. Compared to FIG. 10 a reinforcement layer consisting of a thin conductive polymer film additionally stiffens the crimp area. The conductive polymer film may be applied on either one side of the highly conductive electrode. FIG. 11 shows the case in which the crimp connector and the polymer film are fixed at opposite sides of the highly conductive electrode and the highly conductive electrode was prepared after the preparation of the conductive textile (production scenario A.). The stiffening, conductive polymer film is provided by a conductive layer that is applied on an insulating polymer film. Here the conductive layer is oriented towards the highly conductive textile electrode.

Further embodiments of the textile electrode, especially in the case where the conductive textile is prepared by weaving or knitting of conductive yarns materials, are shown in FIGS. 12 and 13. In these embodiments, additional, structured highly conductive areas are applied on the textile sheet material in order to adjust the electrical properties of specific regions of the material. The highly conductive areas may be composed of the same materials as described hereinabove and may be applied in the same processes as described for the highly conductive electrodes.

These highly conductive structures, however, do not act as electrodes, instead they ensure optimum electrical contacting of conductive yarns in the points of yarn crossings. Hence these structures will be referred to as connecting dots.

The connecting dots solve a typical problem, which frequently occurs in textiles made of conductive yarns. The contact resistance at the yarn crossings largely depends upon the mechanical strain state of the textile. In addition the surface of conductive filaments may alter as a function of time depending on the prevailing environmental conditions. Typically the contact resistance at the yarn crossings increases after such aging.

At those positions on the textile material where a connecting dot is applied, this connecting dot ensures an optimum electrical contact (lowest contact resistance) between the different yarns and yarn filaments in the area of the dot. The connecting dot is most advantageous if yarns of weft and warp direction are crossing within its area.

The connecting dots ensure that all yarns and filaments within its area are at approximately the same electrical potential. In consequence the electrical properties of the above specified conductive textile are drastically enhanced: 1. Its sheet resistance becomes much more homogeneous. 2. Its sheet resistance tends to be lower than without connecting dots. 3. Sheet resistance of the conducting textile with connecting dots is much more robust against local damage of the textile typically accompanied by a local increase of resistance.

Typical arrangements of connecting dots on a conductive textile are shown in FIGS. 12 and 13.

FIG. 12 for instance shows a top view on a conductive textile sheet material. The textile structure is not resolved. Connecting dots are indicated by circles. Connecting dots are applied in an irregular 2D-pattern. Connecting dots may have circular shape of any suitable diameter. Preferably the diameter of a connecting dot is chosen large enough to contain al least one yarn crossing. Connecting dots may have arbitrary shape. Connecting dots may possess different shapes on the same conductive textile. Connecting dots may be interconnected.

FIG. 13 shows a top view on a conductive textile sheet material. The textile structure is not resolved. Connecting dots are indicated by circles. Connecting dots are applied in a periodic 2D-pattern. Different periodic patterns are possible. Periodicity in only one direction is possible. Preferable symmetry axes of connecting dots patterns are tilted with respect to the weft and warp direction of the textile. Connecting dots may have circular shape of any suitable diameter. Preferably the diameter of a connecting dot is chosen large enough to contain al least one yarn crossing. Connecting dots may have arbitrary shape. Connecting dots may possess different shapes on the same conductive textile. Connecting dots may be interconnected.

It will be appreciated that the present invention provides for
Conductive textile that enables capacitive seat occupant sensing.
Conductive textile that enables heating.
Conductive textile that enables both, capacitive seat occupant sensing and heating.
Conductive textile that enables capacitive occupant sensing and maintains its key properties over lifetime (15 years +) in automotive vehicle seating.
Conductive textile that enables heating and maintains its key properties over lifetime (15 years +) in automotive vehicle seating.
Conductive textile that enables both, capacitive seat occupant sensing and heating and maintains its key properties over lifetime (15 years +) in automotive vehicle seating.
Materials and processes to provide textile with conductance in the typical resistance range between 10 and 1000 Ohm.
Materials and processes to create highly conductive textile electrodes in the typical resistance range between 0.01 and 10 Ohm.
Materials and ways to create a conductive textile and structured, highly conductive electrodes on the same textile.
Textile electrode for a capacitive occupant sensor employing a conductive textile with a highly conductive electrode.
Textile electrode for heating in a parallel and in a serial arrangement employing a conductive textile with a highly conductive electrode
Textile electrode for capacitive occupant sensing and heating employing a conductive textile with a highly conductive electrode.
Electrical contacting of highly conductive textile electrodes using ICA
Electrical contacting of highly conductive textile electrodes using crimp connectors
Electrical contacting of highly conductive textile electrodes using crimp connectors and an electromechanical reinforcer made of conductive polymer film.
Conductive polymer film for electromechanical reinforcement of crimp contacts on highly conductive textile electrodes made from a conductive layer on an insulating polymer film. Materials and processes for producing such electromechanical reinforcer.

The functionalized or ‘smart’ textile is a novel and emerging material concept mainly found in the automotive, medicine/health care, and garment market. The market desires material solutions and technical concepts which, make advantage of the unique properties of textiles (flexibility, suppleness, air permeability, cheap R2R production, and finishing process) and combines them with the functionality and long-term stability needed in technical, electronic products. The invention has a direct impact on ODS, OCS, and seat heaters.

1. Textile electrode material comprising an electrically conductive textile sheet material having a first sheet resistance, characterized by an electrically conductive material printed or deposited on said electrically conductive textile sheet material in at least one specific region of said textile sheet material so that in said at least one specific region the textile electrode has a second sheet resistance which is substantially lower than said first sheet resistance.

2. Textile electrode material according to claim 1, in which said textile sheet material comprises a knitted fabric or a woven fabric or an elastic non-woven material made at least partially from electrically conductive yarns.

3. Textile electrode material according to claim 2, wherein said electrically conductive yarns contain fibers of electrically conductive material or fibers individually coated with electrically conductive material.

4. Textile electrode material according to claim 1, wherein said electrically conductive material is printed or deposited in a continuous layer in said at least one specific region on said textile sheet material.

5. Textile electrode material according to claim 1, wherein said electrically conductive material is printed or deposited in locally delimited areas of said at least one specific region on said textile sheet material.

6. (canceled)

7. Capacitive sensing system, comprising a capacitive sensing electrode made of a textile electrode material according to claim 1, and a capacitive sensing circuit for applying a signal to said capacitive sensing electrode or receiving a signal from said capacitive sensing electrode, wherein said capacitive sensing circuit is operatively connected to said at least one specific region.

8. Heating system, comprising a heating element made of a textile electrode material according to claim 1, and a heater supply circuit for applying a heating current to said heating element, wherein said textile electrode material comprises at least two specific regions in which the textile electrode has said second sheet resistance, said two specific regions being arranged at a certain distance one to the other, and wherein said heater supply circuit is operatively connected to said at least two specific regions so as to cause, in operation, a heating current to flow between said at least two specific regions through a region having said first sheet resistance of said textile electrode material.

9. Method for producing a textile electrode material according to claim 1, comprising the steps of:
providing an electrically conductive textile sheet material, said textile sheet material having a first sheet resistance,
printing or depositing an electrically conductive material on said electrically conductive textile sheet material in at least one specific region of said textile sheet material so that in said least one specific region the textile electrode has a second sheet resistance which is substantially lower than said first sheet resistance.

10. Method for producing a textile electrode material according to claim 9, wherein said step of printing or depositing an electrically conductive material on said electrically conductive textile sheet material comprises the printing or depositing of a continuous layer of highly conductive material in said at least one specific region on said electrically conductive textile sheet material.

11. Method for producing a textile electrode material according to claim 9, wherein said step of printing or depositing an electrically conductive material on said electrically conductive textile sheet material comprises the printing or depositing of locally delimited areas of highly conductive material in said at least one specific region on said electrically conductive textile sheet material.

12.-14. (canceled)
